(19) United States
(12) Patent Application Publication
(10) Pub. No.: US 2024/0120252 A1
(43) Pub. Date: Apr. 11, 2024

(54) SEMICONDUCTOR DEVICE

(71) Applicant: RENESAS ELECTRONICS CORPORATION, Tokyo (JP)

(72) Inventors: Nobuhiro KINOSHITA, Tokyo (JP); Mitsunobu WANSAWA, Tokyo (JP)

(21) Appl. No.: 18/358,411

(22) Filed: Jul. 25, 2023

(30) Foreign Application Priority Data
Oct. 6, 2022 (JP) 2022-161628

(51) Int. Cl. H01L 23/367; H01L 23/00; H01L 23/498

(52) U.S. Cl. CPC H01L 23/3675; H01L 23/49816; H01L 23/49838; H01L 23/49894; H01L 24/16; H01L 24/29; H01L 24/32; H01L 24/73; H01L 2224/16227; H01L 2224/2929; H01L 2224/29324; H01L 2224/32245; H01L 2224/73204; H01L 2224/73253; H01L 2924/16235; H01L 2924/16251; H01L 2924/1631; H01L 2924/16598; H01L 2924/3512

(57) ABSTRACT

A semiconductor device according to one embodiment, includes: a wiring substrate having a core insulating layer; a semiconductor chip mounted on an upper surface of the wiring substrate; a plurality of solder balls formed on a lower surface of the wiring substrate; and a heat sink having a first portion fixed to a back surface of the semiconductor chip via a first adhesive layer, and a second portion located around the first portion and fixed to the wiring substrate via a second adhesive layer. Here, a portion of the plurality of solder balls is arranged at a position overlapping with each of the second portion of the heat sink and the second adhesive layer. Also, a second thickness of the second adhesive layer is greater than two times a first thickness of the first adhesive layer.

### CROSS-REFERENCE TO RELATED APPLICATIONS

The disclosure of Japanese Patent Application No. 2022-161628 filed on Oct. 6, 2022, including the specification, drawings and abstract is incorporated herein by reference in its entirety.

### BACKGROUND

The present disclosure relates to a semiconductor device.

Here, there are disclosed techniques listed below. [Patent Document 1] Japanese Unexamined Patent Application Publication No. 2020-4821

In a semiconductor device in which a semiconductor chip is mounted on a wiring substrate in a flip chip bonding method, there is a semiconductor device in which a heat sink (lid) covering the semiconductor chip is bonded onto the wiring substrate (for example, see Patent Document 1).

### SUMMARY

When the heat sink is provided so as to cover the semiconductor chip, the semiconductor chip and the heat sink are bonded to each other via an adhesive layer (chip adhesive layer) that functions as a heat dissipation path. Also, in order to fix the heat sink on the wiring substrate, a peripheral portion (flange portion) of the heat sink is bonded onto the wiring substrate via an adhesive layer (flange adhesive layer). A plurality of solder balls as an external terminal is arranged on a surface opposite a chip mounting surface of the wiring substrate. According to the study by the inventors of the present application, it has been found that a stress is concentrated on a portion of the plurality of solder balls and a breakage (crack) may occur in the solder ball, due to a temperature cycling load during the usage (operation) of the semiconductor device. Further, it has also been found that the breakage of the solder ball may be easily occurred in a solder ball of the plurality of solder balls, which is arranged at a position overlapping with the flange adhesive layer in transparent plan view.

Other objects and novel features will become apparent from the description of this specification and the accompanying drawings.

A semiconductor device according to one embodiment, includes: a wiring substrate having a core insulating layer; a semiconductor chip mounted on an upper surface of the wiring substrate; a plurality of solder balls formed on a lower surface of the wiring substrate; and a heat sink having a first portion fixed to a back surface of the semiconductor chip via a first adhesive layer, and a second portion located around the first portion and fixed to the wiring substrate via a second adhesive layer. Here, a portion of the plurality of solder balls is arranged at a position overlapping with each of the second portion of the heat sink and the second adhesive layer. Also, a second thickness of the second adhesive layer is greater than two times a first thickness of the first adhesive layer.

According to the above-mentioned embodiment, the reliability of the semiconductor device can be improved.

### BRIEF DESCRIPTION OF THE DRAWINGS

FIG. 1 is an upper surface view of a semiconductor device according to one embodiment.

FIG. 2 is a lower surface view of the semiconductor device shown in FIG. 1.

FIG. 3 is a plan view showing an internal structure of the semiconductor device without a heat sink shown in FIG. 1.

FIG. 4 is a cross-sectional view along a line A-A shown in FIG. 1.

FIG. 5 is an enlarged cross-sectional view showing around an adhesive layer bonded to the heat sink shown in FIG. 4.

FIG. 6 is an explanatory view showing a correlation between a thickness of the adhesive layer fixing a flange portion of the heat sink and a product lifetime.

FIG. 7 is an upper surface view showing a semiconductor device with a heat sink which is a modified example to the heat sink shown in FIG. 1.

FIG. 8 is a lower surface view of the semiconductor device shown in FIG. 7.

FIG. 9 is a lower surface view showing a modified example to FIG. 2.

### DETAILED DESCRIPTION

(Description of Form, Basic Term, and Usage in this Application)

In the present application, the description of the embodiment will be divided into a plurality of sections or the like as required for convenience, but unless expressly stated otherwise, these are not independent of each other, and each part of a single example, one of which is a partial detail or a part or all of the other, whether before or after the description, or the like, is modified example or the like. In principle, descriptions of similar parts are omitted. Also, each component in an embodiment is not essential, unless expressly stated otherwise, theoretically limited to that number, and obviously otherwise from the context.

Similarly, in the description of the embodiment and the like, “X comprised of A” or the like with respect to the material, composition, and the like does not exclude elements other than A, except when it is clearly indicated that this is not the case and when it is obvious from the context that this is not the case. For example, regarding a component, it means “X including A as a main component” or the like. For example, the term “silicon member” or the like is not limited to pure silicon, and it is needless to say that it also includes a member containing a SiGe (silicon-germanium) alloy, a multi-element alloy containing silicon as its main component, other additives, or the like. In addition, gold plating, Cu layers, nickel plating, and the like, unless otherwise specified, not only pure, but also gold, Cu, nickel, and the like as the main constituent members, respectively, shall be included.

In addition, reference to a specific numerical value or quantity may be greater than or less than that specific numerical value, unless expressly stated otherwise, theoretically limited to that number, and obviously not so from the context.

In the drawings of the embodiments, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. In addition, hatching or dot patterns may be added to indicate that the region is not a void even if it is not a cross-section or to indicate the boundary of the area.

In the following description, the term “ground plane” or “power supply plane” may be used in some cases. The ground plane and the power supply plane are large-area conductor patterns having a shape different from that of a so-called wiring pattern. Of the large-area conductor patterns, those to which the reference potential is supplied are referred to as a ground plane, and those to which the power supply potential is supplied are referred to as a power supply plane.

<Semiconductor Device>

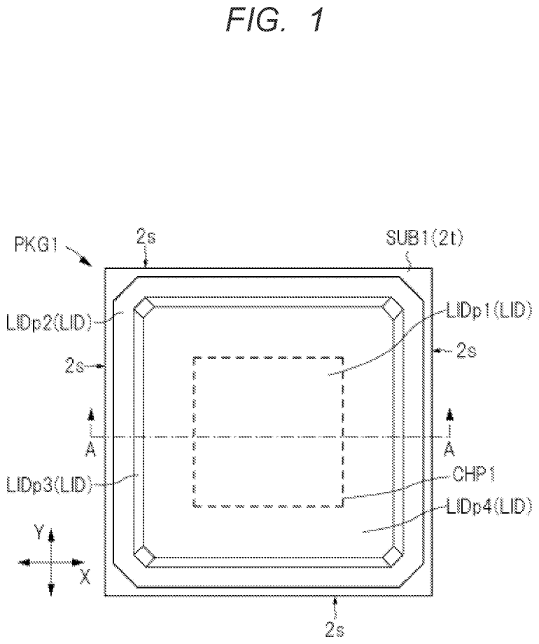

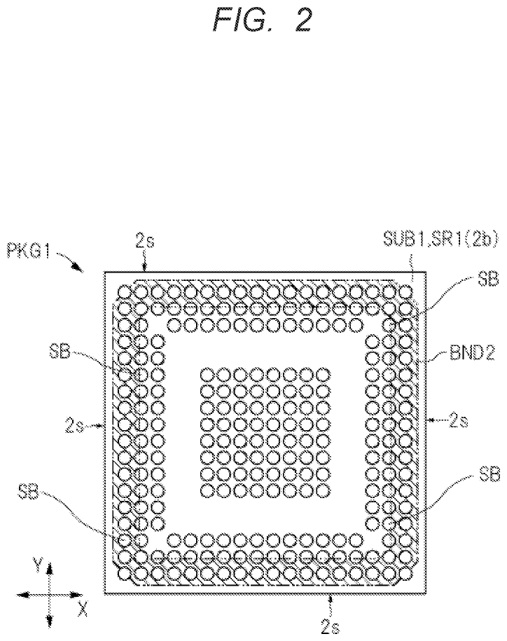

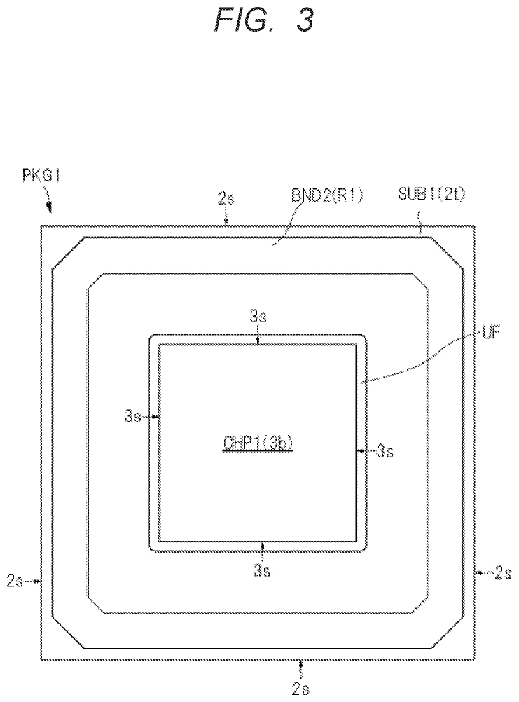

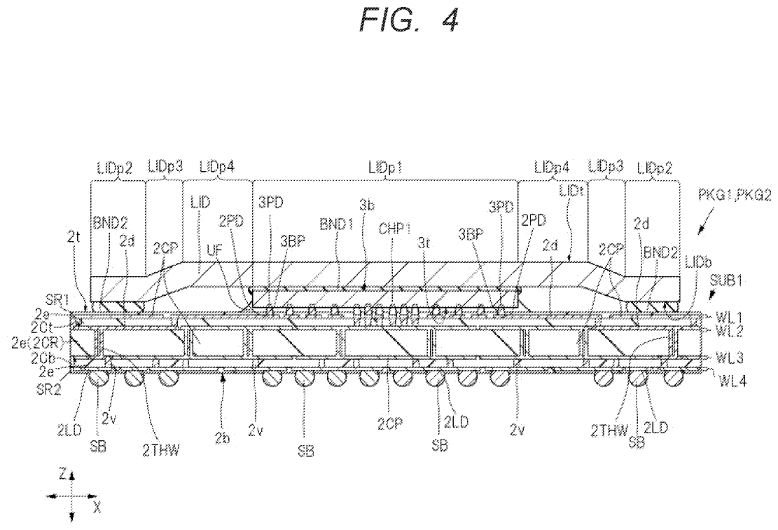

FIG. 1 is an upper surface view of a semiconductor device according to one embodiment. FIG. 2 is a lower surface view of the semiconductor device shown in FIG. 1. FIG. 3 is a plan view showing an internal structure of the semiconductor device without a heat sink shown in FIG. 1. FIG. 4 is a cross-sectional view along a line A-A shown in FIG. 1. In FIG. 1, the outline of a semiconductor chip CHP1 covered with the heat sink (heat dissipation plate) LID is indicated by a dotted line. FIG. 2 is a plan view, but shows a region with hatching (hatch line) overlapping with a portion LIDp2 and an adhesive layer BND2 in order to show a location relationship between a solder ball SB and the portion LIDp2 of the heat sink LID shown in FIG. 1.

A semiconductor device PKG1 of the present embodiment includes a wiring substrate SUB1 and the semiconductor chip CHP1 (see FIG. 3) mounted on the wiring substrate SUB1. The semiconductor device PKG1 includes an adhesive layer BND1 disposed on the semiconductor chip CHP1, and the heat sink LID covering the entire semiconductor chip CHP1, the entire adhesive layer BND1, and a portion of the wiring substrate SUB1.

In recent years, as semiconductor device has become more sophisticated, measures to dissipate heat from a semiconductor chip, which is a main heat source during operation, have become essential. Also, in the semiconductor device PKG1 of the present embodiment, from the viewpoint of stabilizing the operation of the semiconductor chip CHP1, it is preferable that the temperature of the semiconductor chip CHP1 is not excessively increased. For this reason, it is preferable that heat generated in the semiconductor chip CHP1 is efficiently emitted to the outside. In the semiconductor device PKG1, the adhesive layer BND1 are interposed between the semiconductor chip CHP1 and the heat sink LID so that the emission property of heat generated in the semiconductor chip CHP1 can be improved. The heat sink LID is, for example, a metallic plate having a higher thermal conductivity than that of the wiring substrate SUB1, and has a function of discharging heat generated in the semiconductor chip CHP1 to the outside.

As shown in FIG. 4, the heat sink LID is bonded and fixed to the wiring substrate SUB1 via the adhesive layer BND2. The heat sink LID includes a portion (central portion) LIDp1 fixed to a back surface 3b of the semiconductor chip CHP1 via an adhesive layer (chip adhesive layer) BND1, and a portion (peripheral portion, flange portion) LIDp2 located around the portion LIDp1 and fixed to the wiring substrate SUB1 via an adhesive layer (flange adhesive layer) BND2. In the following explanation, the portion LIDp1 is defined as a portion of the heat sink LID that overlaps the semiconductor chip CHP1. In the example illustrated in FIG. 4, the portion LIDp2 is defined as a portion of the heat sink LID that is down-set compared to the portion LIDp1 (in other words, a portion that is disposed at a position lower than the portion LIDp1 and extends in a plane-direction parallel to the portion LIDp1 with an upper surface 2t of the wiring substrate SUB1 as a reference plane). The heat sink LID has a bottom LIDb opposite upper surface LIDt and upper surface LIDt. The lower surface LIDb of the portion LIDp2 corresponds to the adhered surface adhered to the adhesive layer BND2. In the embodiment illustrated in FIG. 4, the entire lower surface LIDb of the portion LIDp2 overlaps the adhesive layer BND2. However, a part of the lower surface LIDb of the portion LIDp2 may not overlap with the adhesive layer BND2. Here, the non-overlapping portion is also included in the above-described portion LIDp2.

As a modified example to FIG. 4, the heat sink LID may not be down-set. Here, the portion LIDp2 is defined as a portion of the heat sink LID that overlaps the adhesive layer BND2.

As another modified example with respect to FIG. 4, the flanged portion located at the peripheral portion of the heat sink LID may be set up at a position higher than the portion LIDp1. In this case, the portion LIDp2 is defined as a part of the heat sink LID that is set up compared to the portion LIDp1 (in other words, a portion that is arranged at a position higher than the portion LIDp1 with respect to the upper surface 2t of the wiring substrate SUB1 as a reference plane, and that extends in a plane direction parallel to the portion LIDp1).

For the present embodiment, the height of the portion LIDp1 of the heat sink LID and the height of the portion LIDp2 differ from each other when the upper surface 2t of the wiring substrate SUB1 is used as a reference surface. In the embodiment of FIG. 4, the portion LIDp2 is arranged at a height closer to the upper surface 2t of the wiring substrate SUB1 than the portion LIDp1. In other words, the portion LIDp2 of the heat sink LID is set to the portion LIDp1 (down-set in FIG. 4). For this reason, in the present embodiment, the heat sink LID includes a portion (a portion, a bent portion, and an inclined portion) LIDp3 disposed between the portion LIDp1 and the portion LIDp2 and subjected to the bending process. In the present embodiment, the heat sink LID includes a portion LIDp4 disposed between the portion LIDp1 and a portion LIDp3. As shown in FIG. 4, the portion LIDp4 does not overlap with the semiconductor chip CHP1, and extends so as to connect the portion LIDp1 and the portion LIDp3 at the same height as the portion LIDp1 with the upper surface 2t of the wiring substrate SUB1 as a reference plane.

The wiring substrate SUB1 has an upper surface (surface, main surface, and chip mounting surface) 2t on which the semiconductor chip CHP1 is mounted, and a lower surface (surface, main surface, and mounting surface) 2b facing away from the upper surface 2t. Each of the upper surface 2t and a lower surface 2b of the wiring substrate SUB1 has a plurality of side 2s (see FIGS. 1 to 3) at its outer edge. For the present embodiment, the upper surface 2t (refer to FIG. 1) and the lower surface 2b (see FIG. 2) of the wiring substrate SUB1 are each square. The upper surface 2t is a chip mounting surface facing the front surface 3t of the semiconductor chip CHP1. For the present embodiment, the length of each of the four sides of the wiring substrate SUB1 is greater than or equal to 20 mm. The problem of fracture occurring in a part of the plurality of solder balls SB described in detail below is likely to be manifested in a relatively large semiconductor device. The semiconductor device PKG1 structure described below can also be applied to a semiconductor device in which the length of each of the four sides of the wiring substrate SUB1 is less than 20 mm. However, in that the problem that fracture is likely to occur in a part of the plurality of solder balls SB is likely to occur, the length of each of the four sides is particularly effective when applied to the semiconductor device PKG1 that is 20 mm or more.

The wiring substrate SUB1 includes a plurality of wiring layers (four layers in the embodiment shown in FIG. 4) WL1, WL2, WL3, and WL4 that electrically connect a terminal (pad 2PD) on the upper surface 2t which is a chip mounting surface and a terminal (land 2LD) on the lower surface 2b which is a mounting surface with each other. Each wiring layer is located between the upper surface 2t and the lower surface 2b. Each wiring layer has a conductor pattern such as a wiring that is a path for supplying an electric signal or electric power. An insulating layer 2e is disposed between the wiring layers. The plurality of insulating layers 2e disposed between the respective wiring layers includes a core insulating layer (insulating layer, core material, core insulating layer) 2CR disposed between the upper surface 2t and the lower surface 2b. The core insulating layer 2CR is a core member for securing the wiring substrate SUB1 rigidity, and is formed of, for example, a prepreg in which fiberglass is impregnated with a resin.

The wiring layers are electrically connected to each other via wiring 2v which is an interlayer conductive path penetrating through the insulating layer 2e or through-hole wiring 2THW. In the present embodiment, as an example of the wiring substrate SUB1, the wiring substrate including four wiring layers is illustrated, but the number of wiring layers included in the wiring substrate SUB1 is not limited to four. For example, a wiring substrate including three or less wiring layers or five or more wiring layers can be used as modified example.

In addition, among the plurality of wiring layers, the wiring layer WL1 disposed closest to the upper surface 2t is covered with the organic insulating film SR1. The organic insulating film SR1 is provided with an opening, and the plurality of pads WL1 provided in the wiring layer 2PD is exposed from the organic insulating film SR1 at the opening. Further, among the plurality of wiring layers, the wiring layer WL4 disposed at a position closest to the lower surface 2b of the wiring substrate SUB1 is covered with the organic insulating film SR2, in which the plurality of lands 2LD id provided. Each of the organic insulating film SR1 and the organic insulating film SR2 is a solder resist film. The plurality of pads 2PD provided in the wiring layer WL1 and the plurality of lands 2LD provided in the wiring layer WL4 are electrically connected to each other via a conductor pattern (a wiring 2d or a large-area conductor pattern 2CP) formed in each wiring layer included in the wiring substrate SUB1, a via wiring 2v, and a through-hole wiring 2THW.

Each of the wiring 2d, the pad 2PD, the via wiring 2v, the via land (not shown), the through-hole land (not shown), the through-hole wiring 2THW, the land 2LD, and the conductor pattern 2CP is made of, for example, copper or a metallic material containing copper as a main component.

The wiring substrate SUB1 is formed, for example, by laminating a plurality of wiring layers on an upper surface 2Ct and a lower surface 2Cb of the core insulating layer (insulating layer, core material, core insulating layer) 2CR by a build-up method. Further, the wiring layer WL2 on the upper surface 2Ct side of the core-insulating layer 2CR and the wiring layer WL3 on the lower surface 2Cb side are electrically connected via a plurality of through-hole wirings 2THW embedded in a plurality of through-holes (through-holes) provided so as to penetrate from one of the upper surface 2Ct and the lower surface 2Cb to the other.

Further, in the exemplary embodiment shown in FIG. 4, a solder ball (solder material, external terminal, electrode, external electrode) SB is connected to each of the plurality of lands 2LD. The solder ball SB is a conductive member that electrically connects a plurality of terminals (not shown) on the motherboard and a plurality of lands 2LD when the semiconductor device PKG1 is mounted on a motherboard (not shown). The solder ball SB is, for example, a so-called lead-free solder material that is Sn—Pb solder material containing lead (Pb) or substantially free of lead (Pb). An example of the lead-free solder is, for example, tin (Sn), tin bismuth (Sn—Bi), tin copper silver (Sn—Cu—Ag), tin copper (Sn—Cu), and the like. Here, the lead-free solder means a solder in which the content of lead (Pb) is 0.1 wt % or less, and this content is determined as a standard of RoHS (Restriction of Hazardous Substances) instruction.

As shown in FIG. 2, the plurality of solder balls SBs is arranged in a matrix. Although not shown in FIG. 2, a plurality of lands 2LD (refer to FIG. 4) to which a plurality of solder balls SB is bonded are also arranged in a matrix. In this way, a semiconductor device in which a plurality of external terminals (solder ball SB, land 2LD) is arranged in a matrix on the mounting surface of the wiring substrate SUB1 is referred to as an area array typed semiconductor device. The area array typed semiconductor device is preferable in that an increase of the mounting area of the semiconductor device can be suppressed even if the number of external terminals increases, because the mounting surface (lower surface 2b) of the wiring substrate SUB1 can be effectively used as an arrangement space for the external terminal. In other words, a semiconductor device in which the number of external terminals increases as the function and integration become higher can be mounted in a space-saving manner.

The semiconductor device PKG1 includes the semiconductor chip CHP1 mounted on the wiring substrate SUB1. As shown in FIG. 4, each of the semiconductor chip CHP1 includes a front surface (main surface, upper surface) 3t in which a plurality of protruding electrodes 3BP are arranged, and a back surface (main surface, lower surface) 3b facing away from the front surface 3t. In addition, each of the front surface 3t and the back surface 3b of the semiconductor chip CHP1 includes a plurality of sides 3s at the outer edge portion. As shown in FIG. 3, the semiconductor chip CHP1 has a quadrangular outer shape having a planar area smaller than that of the wiring substrate SUB1 in a plan view. In the embodiment illustrated in FIG. 3, the semiconductor chip CHP1 is mounted on the wiring substrate SUB1 at the center of the upper surface 2t, and each of the four side 3s of the semiconductor chip CHP1 extends along each of the four side 2s of the wiring substrate SUB1.

Further, a plurality of electrodes (pads, electrode pads, and bonding pads) 3PD is formed on the front 3t of the semiconductor chip CHP1. In the embodiment shown in FIG. 4, the semiconductor chip CHP1 is mounted on the wiring substrate SUB1 with the front surface 3t facing the upper surface 2t of the wiring substrate SUB1. Such a mounting method is called a face-down mounting method or a flip-chip connection method.

Although not shown, a plurality of semiconductor elements (circuit elements) is formed on a main surface of the semiconductor chip CHP1 (specifically, a semiconductor element forming region provided on an element forming surface of semiconductor substrate which is a base material of the semiconductor chip CHP1). The plurality of electrodes 3PD are electrically connected to the plurality of semiconductor elements via wirings (not shown) formed in the wiring layers disposed inside the semiconductor chip CHP1 (specifically, between the front surface 3t and the semiconductor element forming regions (not shown)).

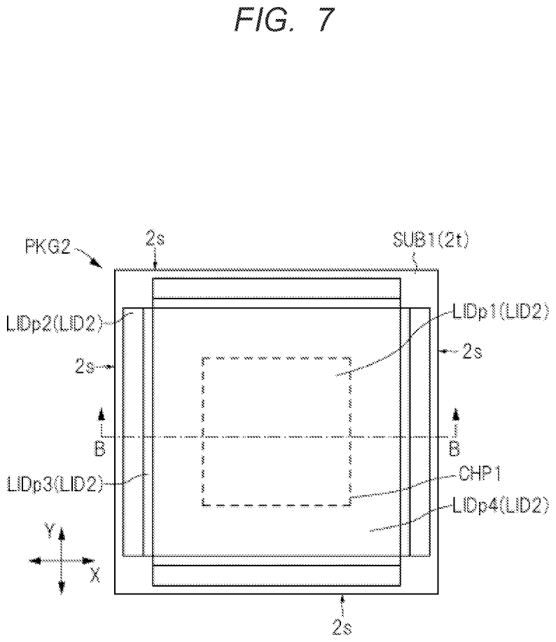

The semiconductor chip CHP1 (in particular, the substrate of the semiconductor chip CHP1) is made of, for example, Si. Further, an insulating film (a passivation film 3PF shown in FIG. 7 to be described later) covering the base material and the wire of the semiconductor chip CHP1 is formed on the front 3t, and a part of each of the plurality of electrode 3PD is exposed from the passivation film in the opening formed in the passivation film. In the present embodiment, the plurality of electrodes 3PD is made of, for example, Al.

Further, as shown in FIG. 4, a plurality of protruding electrodes 3BP is connected to the plurality of electrodes 3PD, respectively, and the plurality of electrodes 3PD of the semiconductor chip CHP1 and the plurality of pads 2PD of the wiring substrate SUB1 are electrically connected with each other, respectively, via the plurality of protruding electrodes 3BP. The protruding electrode (bump electrode) 3BP is a metallic member (conductive member) formed so as to protrude on the front surface 3t of the semiconductor chip CHP1. In the protruding electrode 3BP, in the present embodiment, a columnar electrode made of, for example, copper (so-called kappa pillar electrode) is formed on an electrode 3PD, and a solder material is laminated on a leading end of the columnar electrode. As the solder material laminated on the leading end of the columnar electrode, as in the solder ball SB described above, it is possible to use a lead-containing solder material or lead-free solder.

When the semiconductor chip CHP1 is mounted on the wiring substrate SUB1, a bonding material (for example, a base metal film or a solder paste) having good bonding property with solder is formed in advance on a plurality of pads 2PD. By performing heat treatment (reflow treatment) while the solder material at the end of the columnar electrode and the bonding material on the pad 2PD are contacted with each other, the solder is integrated to form the protruding electrode 3BP. Further, as modified example for the present embodiment, a so-called solder bump in which a columnar electrode made of nickel (Ni) or a micro-solder ball is formed on the electrode 3PD via a base metallic film may be used as the protruding electrode 3BP.

As shown in FIG. 4, an underfill resin (insulating resin) UF is disposed between the semiconductor chip CHP1 and the wiring substrate SUB1. The underfill resin UF is disposed so as to close a space between the front 3t of the semiconductor chip CHP1 and the upper surface 2t of the wiring substrate SUB1. Each of the plurality of protruding electrode 3BP is sealed with an underfill-resin UF. Further, the underfill resin UF is made of an insulating (non-conductive) material (for example, a resin material), and is arranged so as to seal an electrically connecting part (a joint part of a plurality of protruding electrodes 3BP) between the semiconductor chip CHP1 and the wiring substrate SUB1. As described above, by covering the joint portion between the plurality of protruding electrodes 3BP and the plurality of pads 2PD with the underfill resin UF, it is possible to reduce the stresses generated in the electrically connecting portions between the semiconductor chip CHP1 and the wiring substrate SUB1. In addition, stresses occurring at the junction between the plurality of electrodes 3PD of the semiconductor chip CHP1 and the plurality of protruding electrodes 3BP can also be relaxed. Furthermore, it is also possible to protect the main surface on which the semiconductor element (circuit element) of the semiconductor chip CHP1 is formed.

Further, as described above, the heat sink (lid, heat spreader, heat dissipation member) LID is adhered and fixed to the back surface 3b of the semiconductor chip CHP1 via the adhesive layer BND1. The heat sink LID is thermally connected to the semiconductor chip CHP1 via the adhesive layer BND1. The adhesive layer BND1 is in contact with each of the semiconductor chip CHP1 and the heat sink LID.

<Breakage of Solder Ball>

As described above, the area array-type semiconductor device can reduce the mounting area of substrate SUB1 including a large number of external terminals by arranging a large number of solder ball SB on the mounting surface (lower surface 2b). Therefore, as shown in FIG. 2, a large number of solder balls SB are arranged over a wide range of the lower surface 2b of the wiring substrate SUB1. Specifically, in a transmission plan view (FIG. 2 is a transmission plan view when semiconductor device PKG1 is viewed from the lower surface 2b), a part of the plurality of solder balls SB is disposed at a position overlapping the portion LIDp2 and the adhesive layer BND2 (see FIG. 4).

As shown in FIG. 1, the portion LIDp2 of the heat sink LID is disposed in a peripheral area of the wiring substrate SUB1. In the lower surface 2b of substrate SUB1 shown in FIG. 2, a large number of solder balls SB can be arranged in the peripheral area. Therefore, by arranging a large number of solder balls SB in this peripheral area, it is possible to increase the number of external terminals. Further, the transmission path including the solder balls disposed in the peripheral area can be easily connected to the wiring disposed in the uppermost layer or the second wiring layer in a mounting substrate (motherboard) (not shown). For this reason, the solder ball SB constituting the signal transmission path of the electric signal, such as the high-frequency signal, which needs to align the characteristic impedance of the transmission path with the designed value, is often arranged in the peripheral area of the wiring substrate SUB1.

According to studies by the inventors of the present application, it has been found that, in the area-array type semiconductor device in which the heat sink LID is adhesively fixed to each of the wiring substrate SUB1 and the semiconductor chip CHP1, the breakage may occur due to a temperature cycle load during the usage (operation) of the semiconductor device in a part of the solder ball SB disposed at a position overlapping the portion LIDp2 and the adhesive layer BND2, respectively. If the solder balls are broken, the electrical connection reliability is deteriorated. Conversely, by increasing the number of times of the temperature cycling load (in other words, the number of cycles) applied before the breakage occurs, the product lifetime of the semiconductor device can be increased.

The problem that the breakage occurs in the solder ball SB disposed in the regions overlapping the portion LIDp2 and the adhesive layer BND2, respectively, is considered to be one of the reasons that the difference in the linear expansion coefficient between the heat sink LID and the wiring substrate SUB1 is large. When two members having a large difference in the coefficient of linear expansion are bonded and fixed, when the temperature cycling load is applied, a large stress is generated due to the temperature cycling load. Therefore, if the difference in the coefficient of linear expansion between the heat sink LID and the wiring substrate SUB1 can be made small, the stresses can be made small in proportion to the difference, so that the product lifetime can be extended. However, in order to exert a function as a heat dissipation member of the heat sink LID, the material-selection of the heat sink LID needs to be performed in preference to the heat dissipation characteristics. On the other hand, if the wiring substrate SUB1 is made of the same material/structure, the flexibility of designing the wiring layout or the like is reduced.

Therefore, the inventor of the present application focused on the adhesive layer BND2 for bonding the heat sink LID and the wiring substrate SUB1, and studied how to relax the stresses generated by the temperature cycling load by the adhesive layer BND2. However, in view of the manufacturing process of the semiconductor device PKG1, the portions LIDp1 and LIDp2 of the heat sink LID shown in FIG. 4 need to be bonded to the semiconductor chip CHP1 or the wiring substrate SUB1 at the same timing. When the adhesive layer BND1 and the adhesive layer BND2 are made of different adhesive materials, the process of bonding the heat sink LID becomes complicated. Therefore, the adhesive layer BND1 and the adhesive layer BND2 are made of the same material.

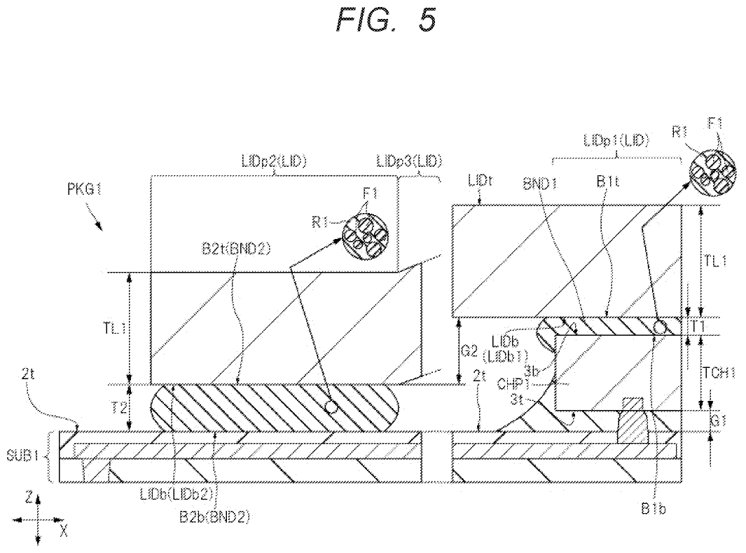

For example, as shown in FIG. 5, the adhesive layer BND1 includes a plurality of fillers F1 included in a resin R1 having an adhesive function. FIG. 5 is an enlarged cross-sectional view showing around an adhesive layer bonded to the heat sink shown in FIG. 4. The filler F1 includes, for example, an alumina filler that is a metallic oxide. The alumina filler is an insulating material having a higher thermal conductivity than that of the adhesive layer BND1. The heat dissipation property of the adhesive layer BND1 can be improved by including a plurality of fillers F1 containing alumina fillers in the adhesive layer BND1. The plurality of fillers F1 may all be an alumina filler, but may also contain a particle that differs from the alumina filler. The adhesive layer BND2 is not required to have a heat dissipation property such as an adhesive layer BND1, but the adhesive layer BND1 and the adhesive layer BND2 include the same kind of filler F1 as each other, in the present embodiment, because the adhesive layer BND1 and the adhesive layer BND2 are made of the same material as each other.

As described above, the material of the adhesive layer BND1 and the material of the adhesive layer BND2 need to be selected as long as the heat dissipation function of the adhesive layer BND1 is not impaired when the adhesive layer BND1 and the adhesive layer BND2 are made of the same material. Therefore, it is difficult to improve the stress-relaxation function by applying an extremely soft material as the material of the adhesive layer BND1 and the adhesive layer BND2. In other words, it is difficult to prevent the solder ball SB from being damaged only by controlling the physical properties of the adhesive layers.

As a result of studies conducted by the inventors of the present application, it was found that the stress relaxing function of the adhesive layer BND2 can be improved by increasing the thickness of the adhesive layer BND2. The adhesive layer BND1 has a thickness T1 that is the shortest distance from one of the contacting surface B1t of the adhesive layer BND1 with the portion LIDp1 of the heat sink LID and the contacting surface B1b of the adhesive layer BND1 with the back surface 3b of the semiconductor chip CHP1 to the other. The adhesive layer BND2 has a thickness T2 that is the shortest distance from one of the contacting surface B2t of the adhesive layer BND2 with the portion LIDp2 of the heat sink LID and the contact surface B2b of the adhesive layer BND2 with the upper surface 2t of the wiring substrate SUB1 to the other. The thickness T2 is greater than two times the thickness T1.

The heat dissipation efficiency in the heat dissipation path through the adhesive layer BND1 is inversely proportional to the thickness T1 of the adhesive layer BND1. Therefore, the thickness T1 is preferably thinner, for example, 50 μm. On the other hand, stresses caused by the above-described temperature cycling load can be relaxed by the adhesive layer BND2 by increasing the thickness T2 of the adhesive layer BND2. The thickness T2 is preferably at least twice as large as the thickness T1 (e.g., 100 μm), and particularly preferably three times or more (e.g., 150 μm). Even if the material of the adhesive layer BND1 and the material of the adhesive layer BND2 are selected in preference to the heat dissipation property of the adhesive layer BND1, the product lifetime can be extended.

Examples of dimensions of the example shown in FIG. 5 are as follows, for example. The thickness T1 is, for example, 50 μm as described above. The thickness TCH1 of the semiconductor chip CHP1 defined as the distance from one of the front surface 3t and the back surface 3b to the other is, for example, 400 μm. The gap G1 defined as the shortest distance between the front 3t of the semiconductor chip CHP1 and the upper surface 2t of the wiring substrate SUB1 is, for example, 75 μm. The thickness TL1 of the heat sink LID is, for example, 500 μm. For the present embodiment, the thickness TL1 of the portion LIDp1 and the thickness TL1 of the portion LIDp2 are the same thickness as each other.

In the present embodiment, the heat sink LID has the portion LIDp3 as a bent portion subjected to bending between the portion LIDp1 and the portion LIDp2. The configuration of the heat sink LID shown in FIGS. 4 and 5 can also be expressed as follows. The lower surface LIDb of the heat sink LID has a lower surface LIDb1 of the portion LIDp1 and a lower surface LIDb2 of the portion LIDp2. The lower surface LIDb1 faces the semiconductor chip CHP1 via the adhesive layer BND1, and the lower surface LIDb2 faces the upper surface 2t of the wiring substrate SUB1 via the adhesive layer BND2. The shortest distance from the lower surface LIDb2 of the portion LIDp2 to the upper surface 2t of the wiring substrate SUB1 is less than the shortest distance from the lower surface LIDb1 of the portion LIDp1 to the upper surface 2t of the wiring substrate SUB1.

The degree of bending, in other words, the height differential G2 between the lower surface LIDb1 of the portion LIDp1 and the lower surface LIDb2 of the portion LIDp2 is, for example, about 350 μm. Here, the thickness T2 of the adhesive layer BND2, defined as the shortest distance from one of the contact surface B2t and the contact surface B2b to the other, is 175 μm. Note that in the wiring substrate SUB1, “warpage deformation” in which the central area of the semiconductor chip CHP1 is convex toward the upper surface 2t may occur due to a thermal effect (for example, a reflow process when the semiconductor chip CHP1 is mounted on the wiring substrate SUB1) during the manufacturing process. Considering this warp deformation, the distance from one of the contact surface B2t and the contact surface B2b to the other is not constant, and may increase as the distance approaches the peripheral portion. The average value of the distances from one of the contact surface B2t and the contact surface B2b to the other in the regions overlapping the portion LIDp2 and the adhesive layer BND2 is approximately 200 μm.

<Evaluation of Correlation Between Thickness of Adhesive Layer and Product Lifetime>

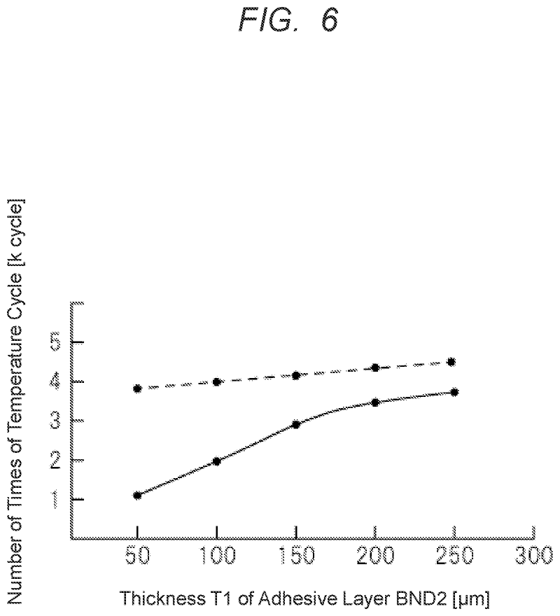

Next, with regard to an effect of the extended product lifetime by increasing the thickness T2 of the adhesive layer BND2, the result of the study by the inventor of the present application will be described. FIG. 6 is an explanatory view showing a correlation between a thickness of the adhesive layer fixing a flange portion of the heat sink and a product lifetime. In FIG. 6, the horizontal axis represents a value of the thickness T2 shown in FIG. 5. The vertical axis represents the number of times of the temperature cycling load until a breakage is found in the solder ball SB arranged at a position overlapping with each of the portion LIDp2 and the adhesive layer BND2 shown in FIG. 4, as an indicator of the product lifetime. In addition, FIG. 6 shows an evaluation result using two types of materials as an adhesive material of the adhesive layer BND2 (refer to FIG. 5).

The test section indicated by the solid line shows the result of the test using the adhesive material satisfying the requirement of the heat dissipation property when used as the material of the adhesive layer BND1 shown in FIG. 5. The test zone indicated by the dotted line shows the result of testing using an adhesive material having a relatively low storage modulus (storage elastic modulus) at 0 degrees Celsius compared to the adhesive material of the test zone indicated by the solid line. Incidentally, for the adhesive material used in the test group indicated by the dotted line, when used as an adhesive material of the adhesive layer BND1 shown in FIG. 5 (thickness T1 is 50 μm), since the heat dissipation performance does not reach the target value, the adhesive layer BND1 and the adhesive layer BND2 needs to be a different material, it is described as a reference of the test result of the test group indicated by the solid line. For example, in the values actually measured by the measuring methods described below by the inventor of the present application, the storage modulus at 0 degrees Celsius of the adhesive material used in the test section of the solid line was 132 MPa (megapascals), the storage modulus at 0 degrees Celsius of the adhesive material used in the test section of the dotted line was 11.1 MPa (megapascals).

The semiconductor device used for measuring the assessment shown in FIG. 6 is as follows. That is, the thickness T1 shown in FIG. 5 is 50 μm, the thickness TCH1 is 400 μm, the gap G1 is 75 μm, and the thickness TL1 is 500 μm. The value of the thickness T2 was adjusted by changing the value of the height difference G2. The length of each of the four side 2s of the wiring substrate SUB1 shown in FIG. 3 is 25 mm. The length of each of the four sides of the front 3t of the semiconductor chip CHP1 is about 10 mm. The thickness of the wiring substrate SUB1 shown in FIG. 4 (i.e., the distance from one of the upper surface 2t and the lower surface 2b to the other) is about 580 μm.

As shown in FIG. 6, it can be seen that the product lifetime can be extended in proportion to the thickness T2 of the adhesive-layer BND2 in each of the test section of the solid line and the test section of the dotted line. In the test section of the solid line, the number of times of the temperature cycling load applied until the breakage of the solder ball SB occurs, the value of the thickness T2 shown in FIG. 5 is about 2000 cycles when the value of the thickness T1 is twice (100 μm), three times (150 μm) was about 3000 cycles. When the target value of the number of times of the temperature cycling load applied until the breakage of the solder ball SB occurs is 2000 cycles, if the value of the thickness T2 is larger than twice the value of the thickness T1, it is possible to achieve this even when considering the margin due to experimental error.

As will be described later, breakage may also occur in a solder ball SB disposed in an area overlapping with the semiconductor chip CHP1 shown in FIG. 4. However, by making the thickness of the wiring substrate SUB1 as 500 μm to 1 mm, the number of times of the temperature cycling load applied until the breakage of the mender ball SB arranged in the region superimposed with the semiconductor chip CHP1 occurs can be as much as 4000 cycles from 3000 cycles, as determined by the study of the present inventor. Therefore, for the solder ball SB disposed in the area overlapping with the adhesive layer BND2, it is preferable that the number of times of the temperature cycling load applied until the fracture occurs is 3000 cycles or more. From this viewpoint, it is particularly preferable that the value of the thickness T2 is 3 times or more of the value of the thickness T1.

Further, it is considered that the number of times of the temperature cycling load is not less than 3000 cycles even if the depth T2 is greater than 250 μm. Therefore, there is no particular upper limit in the thickness T2 of the adhesive layer BND2 from the viewpoint of extending the product lifetime of the solder ball SB disposed in the regions overlapping the portion LIDp2 and the adhesive layer BND2, respectively. For example, although not shown in the drawings, as a modified example to the present embodiment, there are cases where a portion (a portion, a bent portion, or an inclined portion) subjected to the bending process shown in FIG. 4 is not provided, and the lower surface LIDb1 of the portion LIDp1 shown in FIG. 5 and the lower surface LIDb2 of the portion LIDp2 are positioned at the same height (in other words, the height difference G2 is 0) with respect to the upper surface 2t of the wiring substrate SUB1 as a reference surface. Further, for example, as another modified example to the present embodiment, the lower surface LIDb2 of the portion LIDp2 illustrated in FIG. 5 may be disposed at a higher position with respect to the lower surface LIDb1 of the portion LIDp1 with respect to upper the surface 2t of the wiring substrate SUB1 as a reference surface (in other words, the portion LIDp3 illustrated in FIG. 4 is set up).

However, as can be seen from the test section of the solid line shown in FIG. 6, after the thickness T2 exceeds 150 μm, the thickness T2 is gradually increased. In addition, considering the ease of working when adhering and fixing the heat sink LID shown in FIG. 4 on the upper surface 2t of the wiring substrate SUB1, the thickness T2 of the adhesive-layer BND2 is preferable not extremely thick. For example, the thickness T2 of the adhesive layer BND2 is preferably equal to or less than the shortest distance from the portion LIDp1 of the heat sink LID to upper surface 2t of the wiring substrate SUB1. In other words, the thickness BND2 of the adhesive layer T2 is preferable equal to or less than the sum of the gap G1 between the upper surface 2t of the wiring substrate SUB1 and the semiconductor chip CHP1, the thickness TCH1 of the semiconductor chip CHP1, and the thickness T1 of the adhesive layer BND1.

Furthermore, as in the present embodiment, it is particularly preferable that the shortest distance from the lower surface LIDb2 of the portion LIDp2 to the upper surface 2t of the wiring substrate SUB1 is less than the shortest distance from the lower surface LIDb1 of the portion LIDp1 to the upper surface 2t of the wiring substrate SUB1.

Further, as shown in FIG. 6, when the thickness T2 of the adhesive layer BND2 is 5 times (250 μm) the thickness T1, the number of times of the temperature cycling load is less than 4000 cycles (about 3800 cycles to 4000 cycles). When the number of times the temperature cycling load increases to this extent, breakage may occur in the solder ball SB disposed in the area overlapping with the semiconductor chip CHP1 shown in FIG. 4. In order to extend the product lifetime of semiconductor device PKG1, attention needs to be paid to a solder ball SB disposed in an area overlapping with the portion LIDp2 and the adhesive layer BND2, respectively. From this viewpoint, the value of the thickness T2 shown in FIG. 5 is preferable 5 times (250 μm) or less of the value of the thickness T1. Accordingly, the heat sink LID can be stably adhesive and fixed on the wiring substrate SUB1 while suppressing damages to the solder balls that are particularly easily broken.

<Evaluation of Correlation Between Storage Elastice Modulus of Adhesice Material and Product Lifetime>

Next, a storage modulus of the entire adhesive material composing the adhesive layer BND2 will be described. It is preferable to be able to relax the stress by the adhesive layer BND2 in order to reduce the stress generated in the portion LIDp2 and the adhesive layer BND2 shown in FIG. 4 when the temperature cycling load is applied to the solder ball SB disposed in the overlapping regions. This stress-relaxation property can be improved by increasing the thickness of the adhesive layer BND2 as described above, but it is preferable that the adhesive material constituting the adhesive layer BND2 is also soft (easily elastically deformed). The inventor of the present application adopted the storage modulus as an index for evaluating the softness of the adhesive material constituting the adhesive layer BND2.

The storage modulus is a component of a dynamic elastic modulus, and is a component of energy generated by an external force and strain on an object that is stored inside the object. A component of the dynamic elastic modulus that diffuses to the outside of the object is a loss elastic modulus. This time, the storage modulus in the tensile mode was used as an index to evaluate the stress-relaxation properties of the adhesive layer BND2 for the temperature cycling load.

First, as a test piece for measurement, a strip-shaped test piece made of a material to be tested is prepared. The test specimens measured by the present inventors are 10 mm wide, length 60 mm, and thickness of 500 μm. As device, a dynamic viscoelasticity measurement device was used. In the measurement, in a state in which one end portion in the longitudinal direction of the test piece is fixed, the probe holding the other end portion vibrates in the longitudinal direction of the test piece. In the present study, the frequency of oscillation was 1 Hz. In addition, the environmental temperature at the time of measurement was stepped up from −65 degrees Celsius to 300 degrees Celsius every 5 degrees Celsius, and the measurement was performed at each temperature, and the storage modulus at 0 degrees Celsius was used as an evaluation index.

First, the storage modulus at 0 degrees Celsius was 132 MPa (megapascals) for the adhesive of the test plot indicated by the solid line in FIG. 6. On the other hand, in FIG. 6, the storage modulus at 0 degrees Celsius was 11.1 MPa for the adhesive of the test section indicated by the dotted line. Further, although not shown in FIG. 6, the storage modulus was also measured for the adhesive material harder than the adhesive material used in the test group shown in FIG. 6. According to studies conducted by the inventors of the present application, it was found that when the storage modulus at 0 degrees Celsius is equal to or less than 200 MPa, the same result as those obtained in the test plot indicated by the solid line in FIG. 6 can be obtained.

In addition to the test section shown in FIG. 6, the product life was evaluated using a material of 3.89 GPa (gigapascal) as a material having an extremely high storage modulus at 0 degrees Celsius. It was confirmed that the product lifetime could be extended by increasing the thickness T2, but the number of times of the temperature cycling load applied until the breakage of the solder ball SB occurred was about 70% (measured value 69.4%) with respect to the test section shown by the solid line in FIG. 6. Therefore, it is preferable that the storage modulus of the adhesive material constituting the adhesive layer BND2 shown in FIG. 5 at 0 degrees Celsius is equal to or less than 200 MPa.

In addition, when the adhesive material used in the test section indicated by the dotted line in FIG. 6 is used as the material of the adhesive layer BND1 shown in FIG. 5, the heat dissipation property is insufficient. However, from the viewpoint of the stress-relaxation property, the storage modulus at 0 degrees Celsius is preferably 11.1 MPa. Therefore, the storage modulus at 0 degrees Celsius is not particularly limited as long as it satisfies the required specifications from the viewpoint of heat dissipation properties, and it is sufficient if it is larger than 0 Pa (Pascal).

<Breakage of Solder Ball Arranged in Region Overlapping with Semiconductor Chip>

Next, the breakage of the solder ball SB disposed in an area overlapping the semiconductor chip CHP1 among the plurality of solder balls SB shown in FIG. 4 will be described. As described above, the inventors of the present application focused on the breakage occurring in the solder ball SB disposed in the area overlapping the adhesive layer BND2 for bonding and fixing the heat sink LID to the wiring substrate SUB1, and studied how to suppress the generation. However, even when breakage occurs in the solder ball SB disposed in regions other than the regions overlapping the portion LIDp2 and the adhesive layer BND2 described above, the reliability of semiconductor device PKG1 is lowered. In particular, when the difference between the linear expansion coefficient of the semiconductor chip CHP1 and the linear expansion coefficient of the wiring substrate SUB1 is large, breakage is likely to occur in the solder ball SB disposed in the area overlapping the semiconductor chip CHP1.

According to studies by the inventors of the present application, by reducing the thickness of the core insulating layer 2CR and the thickness of the semiconductor chip CHP1 of the wiring substrate SUB1 shown in FIG. 4, it was found that breakage of the solder ball SB disposed in the regions overlapping the semiconductor chip CHP1 can be suppressed. Specifically, it has been found that the thickness TL1 of the portion LIDp1 of the heat sink LID shown in FIG. 5 is preferably larger than the thickness TCH1 of the semiconductor chip CHP1 shown in FIG. 5 and the thickness (upper surface 2Ct and lower surface 2Cb) of the core insulating layers 2CR shown in FIG. 4. For example, in the embodiment illustrated in FIG. 4, the thickness of the core insulating layer 2CR is 410 μm. Therefore, the thickness TL1 (for example, 500 μm) of the portion LIDp1 of the heat sink LID shown in FIG. 5 is larger than the thickness TCH1 (for example, 400 μm) of the semiconductor chip CHP1 and the thickness of the core insulating layer 2CR shown in FIG. 4. In addition, from the viewpoint of suppressing the breakage of the solder ball SB arranged in the region overlapping with the semiconductor chip CHP1, it is particularly preferable that the thickness of the core insulating layer 2CR is larger than the thickness TCH1 of the semiconductor chip CHP1.

If the above conditions are satisfied, the solder ball SB disposed in the region overlapping the semiconductor chip CHP1 and the region overlapping the portion LIDp2 and the adhesive layer BND2 tend to break prior to breakage occurs in the solder ball SB disposed in the region overlapping (refer to FIG. 4). Further, with respect to the solder ball SB arranged in the region overlapping the semiconductor chip CHP1, by the above countermeasures, it is possible to increase the number of times of the temperature cycling load until breakage occurs. Therefore, according to the present embodiment, the product lifetime of semiconductor device as a whole can be extended.

<Modified Example of Shape of Heat Sink>

Next, a modified example of the shape of the heat sink LID shown in FIG. 1 will be described. FIG. 7 is an upper sur face view showing a semiconductor device with a heat sink which is a modified example to the heat sink shown in FIG. 1.

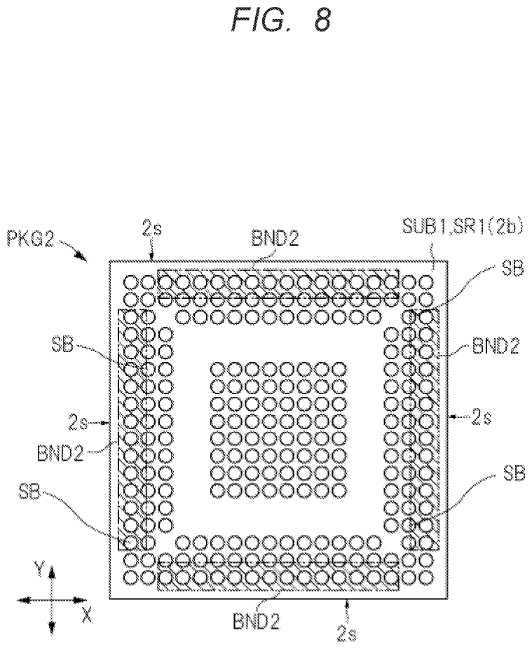

FIG. 8 is a lower surface view of the semiconductor device shown in FIG. 7. Since the cross-sectional view along a line B-B shown in FIG. 7 is the same as the cross-sectional view shown in FIG. 4, the illustration is omitted and will be described with reference to FIG. 4 as needed.

The heat sink LID2 of a semiconductor device PKG2 shown in FIGS. 7 and 8 is different from the heat sink LID shown in FIG. 1 in that the portion LIDp2 is not formed around the four corners of the wiring substrate SUB1 forming a square in plan view. Specifically, the heat sink LID2 includes a portion LIDp1 overlapping with the semiconductor chip CHP1, and four portions LIDp2 disposed around the portion LIDp1 and adhesively fixed to the upper surface 2t of the wiring substrate SUB1 via an adhesive layer BND2 (refer to FIG. 4).

Each of the four portions LIDp2 is arranged along each side of the portion LIDp1 forming a quadrangle in plan view and is spaced apart from each other. Further, in the embodiment shown in FIG. 7, the heat sink LID2 includes a portion (a portion, a bent portion, an inclined portion) LIDp3 disposed between the portion LIDp1 and the portion LIDp2 and subjected to bending. Further, the heat sink LID2 includes the portion LIDp4 disposed between the portion LIDp1 and the portion LIDp3. As shown in FIG. 4, the portion LIDp4 does not overlap with the semiconductor chip CHP1, and extends so as to connect the portion LIDp1 and the portion LIDp3 at the same height as the portion LIDp1 with the upper surface 2t of the wiring substrate SUB1 as a reference plane.

As described above, in the case of the heat sink LID2, it can be expressed as follows that the portion LIDp2 is not formed around the four corner portions of the wiring substrate SUB1. That is, each of the four portions LIDp2 included in the heat sink LID2 extends in any one of the X direction and the Y direction perpendicular to the X direction. No other portions LIDp2 are arranged on the respective extension of the four portions LIDp2.

Although not shown, when the planar shape of the outer edge of the portion LIDp2 is a quadrangle, breakage of the solder ball SB (see FIG. 4) described above is likely to occur in the vicinity of the corners of the quadrangle. This is because stress tends to concentrate on the square corners. In the present modified example, as shown in FIG. 8, the solder ball SB disposed around the four corners of the wiring substrate SUB1 do not overlap the adhesive layer BND2. Therefore, it is possible to avoid concentration of stresses in the solder ball SB in particular fracture is likely to occur, it is possible to increase the number of times of the temperature cycling load until the fracture occurs. That is, the product life can be extended.

<Modified Example of Solder Ball Array>

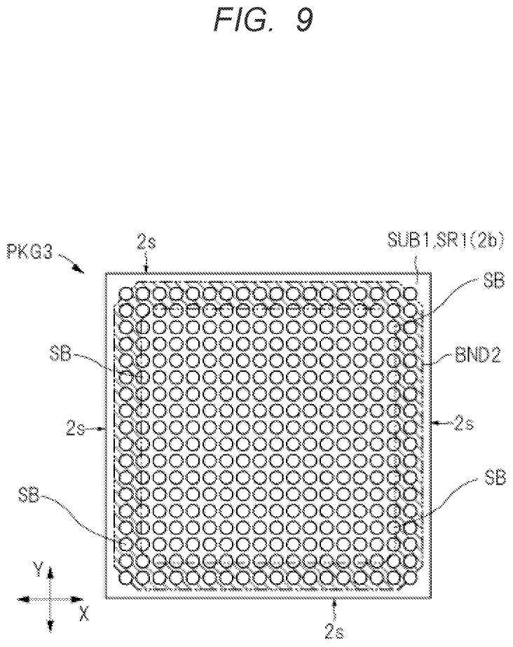

Next, modified example of the arrangement of the solder ball SB shown in FIG. 2 will be described. FIG. 9 is a lower surface view showing a modified example to FIG. 2. Although FIG. 2 shows an exemplary layout of a plurality of solder balls SB, the layout of the solder ball SB includes various modified example in addition to the embodiment shown in FIG. 2. For example, in a semiconductor device PKG3 shown in FIG. 9, the solder ball SB are arranged at equal intervals on the matrix, so-called full-grid layout. The techniques described with reference to FIGS. 1-8 may be applied to the semiconductor device PKG3 of a full grid array as shown in FIG. 9.

Although the invention made by the present inventor has been specifically described based on the embodiment, the present invention is not limited to the above embodiment, and it is needless to say that various modifications can be made without departing from the gist thereof.

What is claimed is:

1. A semiconductor device comprising:
a wiring substrate having an upper surface, a lower surface opposite the upper surface, and a core insulating layer located between the upper surface and the lower surface;
a semiconductor chip having a first surface, a plurality of protruding electrodes, and a second surface opposite the first surface, the semiconductor chip being mounted on the wiring substrate via the plurality of bump electrodes such that the first surface faces the upper surface of the wiring substrate;
a plurality of solder balls formed on the lower surface of the wiring substrate; and
a heat sink having a first portion fixed to the second surface of the semiconductor chip via a first adhesive layer, and a second portion located around the first portion and fixed to the wiring substrate via a second adhesive layer,
wherein, in transparent plan view, a portion of the plurality of solder balls is arranged at a position overlapping with each of the second portion of the heat sink and the second adhesive layer,
wherein the first adhesive layer and the second adhesive layer include a same kind of filler as each other, and
wherein when a shortest distance from a contacting surface of the first adhesive with the first portion of the heat sink to a contacting surface of the first adhesive with the second surface of the semiconductor chip is assumed to a first thickness, and when a shortest distance from a contacting surface of the second adhesive with the second portion of the heat sink to a contacting surface of the second adhesive with the upper surface of the wiring substrate is assumed to a second thickness, the second thickness is greater than two times the first thickness.

2. The semiconductor device according to claim 1, wherein the second thickness is less than or equal to a shortest distance from the first portion of the heat sink to the upper surface of the wiring substrate.

3. The semiconductor device according to claim 1,
wherein the heat sink having:
a first lower surface facing the second surface of the semiconductor chip via the first adhesive layer; and
a second lower surface facing the upper surface of the wiring substrate via the second adhesive layer, and
wherein a shortest distance from the second lower surface of the heat sink to the upper surface of the wiring substrate is less than a shortest distance from the first lower surface of the heat sink to the upper surface of the wiring substrate.

4. The semiconductor device according to claim 3, wherein the second thickness is less than or equal to five times the first thickness.

5. The semiconductor device according to claim 1, wherein each of the first adhesive layer and the second adhesive layer includes an aluminum filler.

6. The semiconductor device according to claim 1, wherein a storage modulus of each of the first adhesive layer and the second adhesive layer is greater than 0, and less than or equal to 200 MPa.

7. The semiconductor device according to claim 1,
wherein a thickness of the first portion of the heat sink and a thickness of the second portion of the heat sink are the same as each other, and
wherein the thickness of the first portion of the heat sink is greater than a thickness of the core insulating layer of the wiring substrate, and greater than a thickness of the semiconductor chip.

8. The semiconductor device according to claim 1,
wherein, in plan view, the wiring substrate is comprised of a quadrangular shape, and
wherein, in plan view, a length of each of four sides of the wiring substrate is greater than and equal to 20 mm.
